(19) United States
(12) Patent Application Publication
(10) Pub. No.: US 2005/0285112 A1
(43) Pub. Date: Dec. 29, 2005

(54) Thin film transistor and method for fabricating the same

(76) Inventors: Eui-Hoon Hwang, Suwon (KR); Keun-Soo Lee, Suwon-si (KR)

Correspondence Address: MCGUIREWOODS, LLP, 1750 TYSONS BLVD, SUITE 1800, MCLEAN, VA, 22102, US

(21) Appl. No.: 11/168,922

(22) Filed: Jun. 29, 2005

(30) Foreign Application Priority Data
Jun. 29, 2004 (KR) 2004-49826

(51) Int. Cl. H01L 29/10

(52) U.S. Cl. 257/66

(57) ABSTRACT

The present invention provides a thin film transistor in which a semiconductor layer and a gate insulation film of the thin film transistor are formed by depositing a second insulation film on a polycrystalline silicon layer pattern and a first insulation film pattern that were formed by first crystallizing and then patterning an amorphous silicon layer covered by a continuously formed first insulation layer or first patterning and then crystallizing a previously formed amorphous silicon layer covered by a continuously formed first insulation film that is a part of the gate insulation film, and a method for fabricating the thin film transistor.

### CROSS REFERENCE TO RELATED APPLICATIONS

This application claims priority to Korean Patent Application No. 10-2004-0049826, filed on Jun. 29, 2004, the disclosure of which is herein incorporated by reference in its entirety.

### BACKGROUND OF THE INVENTION

1. Field of the Invention

The present invention relates to thin film transistors generally and, more particularly, to a thin film transistor in which a second insulation film is deposited on a first insulation film that covers a polysilicon layer, which was formed by first crystallizing and then patterning an amorphous silicon layer covered by a continuously formed first insulation layer or which was formed by first patterning and then crystallizing an amorphous silicon layer covered by a continuously formed first insulation film. Together, the polysilicon layer and the first insulation film may form part of a gate insulation film. The present invention also discloses a method for fabricating the thin film transistor.

2. Description of Related Art

FIG. 1 is a cross-sectional view of a conventional thin film transistor 10.

As illustrated in FIG. 1, a semiconductor layer 13 is formed by patterning a polycrystalline or monocrystalline silicon layer after forming a buffer layer 12 on an insulation substrate 11 such as plastic or glass. The polycrystalline or monocrystalline silicon layer is created by forming an amorphous silicon layer on the buffer layer and crystallizing the amorphous silicon layer to form either a polycrystalline or a monocrystalline silicon layer.

The buffer layer prevents diffusion of moisture or impurities generated from a lower substrate or controls the heat transfer rate during crystallization so that crystallization of the semiconductor layer is uniform.

The amorphous silicon layer may be deposited using either a chemical vapor deposition or a physical vapor deposition process. Additionally, a dehydrogenation treatment may be performed when forming, or after forming, the amorphous silicon layer. Such a treatment lowers the concentration of hydrogen in the amorphous silicon layer. The amorphous silicon layer may be crystallized using a crystallization method (or methods) selected from a group including, but not limited to rapid thermal annealing, solid phase crystallization, excimer laser annealing, metal induced crystallization, metal induced lateral crystallization and sequential lateral solidification.

Next, a gate electrode 15 is produced by first forming a gate insulation film 14 on the front surface of a substrate on which the semiconductor layer is formed and depositing a gate electrode forming material on the gate insulation film 14, and then patterning the gate electrode forming material. After the gate electrode is formed, it is used as a mask during an impurity ion implantation process to define one or more source/drain and channel regions on the semiconductor layer.

Subsequently, an interlayer insulation film 16 is formed on the front surface of the substrate to protect or electrically insulate elements formed under the interlayer insulation film. The buffer layer, the gate insulation film and the interlayer insulation film are formed by using an oxide film such as silicon oxide or a nitride film such as silicon nitride.

Thereafter, the conventional thin film transistor is completed by forming contact holes on the interlayer insulation film to expose the source/drain regions formed on the semiconductor layer depositing source/drain electrode materials on the front surface of the substrate, and then patterning the source/drain electrode materials, thereby forming source/drain electrodes 17.

However, the conventional thin film transistor 10 includes undesired oxides and contaminants that result from forming a photoresist pattern. Additionally, an etching gas or an etching solution may easily form on the surface of the semiconductor layer and a separate cleaning process is required to remove the oxides or the contaminants. Moreover, defects such as mismatch of grain orientation are generated on the interface between the semiconductor layer and the gate insulation film. Such defects reduce electron mobility and increase leakage current when the exposed surface of the amorphous silicon layer is crystallized to form the polycrystalline silicon layer and the polycrystalline silicon layer is thereafter patterned.

### SUMMARY OF THE INVENTION

Therefore, in order to solve the foregoing demerits and problems of the prior art, the present invention provides a thin film transistor in which a semiconductor layer and gate insulation film are formed by depositing a second insulation film on a polycrystalline silicon layer pattern and a first insulation film pattern that were formed by crystallizing and patterning the amorphous silicon layer or that were formed by patterning and crystallizing the amorphous silicon layer and the first insulation film after continuously forming the amorphous silicon layer and the first insulation film that is part of the gate insulation film. The invention also provides a method for fabricating the thin film transistor.

A thin film transistor constructed according to the principles to the invention may include: a substrate; a polycrystalline silicon layer pattern continuously covered by a first insulation film pattern and formed on the substrate; a second insulation film formed on the first insulation film pattern; and a gate electrode formed on the second insulation film; and an interlayer insulation film formed on the second insulation film and the gate electrode.

Furthermore, the present invention provides a method for fabricating a thin film transistor film. The method may comprise the steps of forming an amorphous silicon layer on an substrate; continuously forming a first insulation film on the amorphous silicon layer; forming a polycrystalline silicon layer pattern and a first insulation film pattern out of the amorphous silicon layer and first insulation film; forming a second insulation film on the substrate; forming a gate electrode on the second insulation film; and forming an interlayer insulation film on the gate electrode and the second insulation film.

### BRIEF DESCRIPTION OF THE DRAWINGS

The above and other features and advantages of the present invention will become more apparent to those of ordinary skill in the art by describing in detail preferred embodiments thereof with reference to the attached drawings.

FIG. 1 is a cross-sectional view of a conventional thin film transistor.

FIG. 2A, FIG. 2B, FIG. 2C, and FIG. 2D are cross-sectional views illustrating a process of fabricating a thin film transistor according to the present invention.

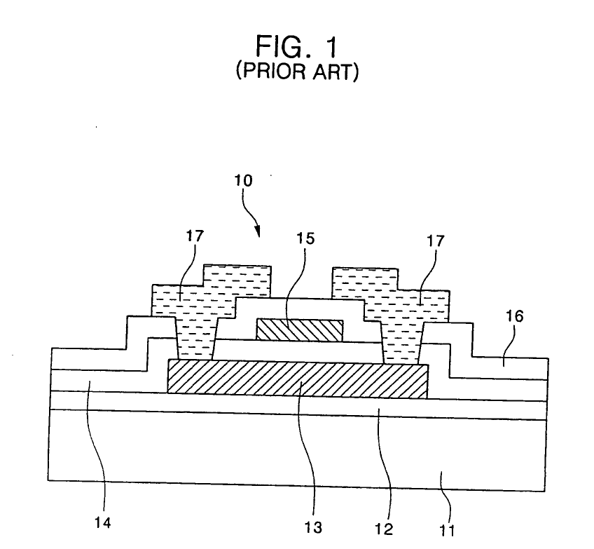

### DETAILED DESCRIPTION OF THE INVENTION

The embodiments of the invention and the various features and advantageous details thereof are explained more fully with reference to the non-limiting embodiments and examples that are described and/or illustrated in the accompanying drawings and detailed in the following description. It should be noted that the features illustrated in the drawings are not necessarily drawn to scale, and features of one embodiment may be employed with other embodiments as the skilled artisan would recognize, even if not explicitly stated herein. Descriptions of well-known components and manufacturing techniques may be omitted so as to not to unnecessarily obscure the embodiments of the invention. The examples used herein are intended merely to facilitate an understanding of ways in which the invention may be practiced and to further enable those of skill in the art to practice the embodiments of the invention. Accordingly, the examples and embodiments herein should not be construed as limiting the scope of the invention, which is defined solely by the appended claims and applicable law. Moreover, it is noted that like reference numerals may represent similar parts throughout the several views of the drawings.

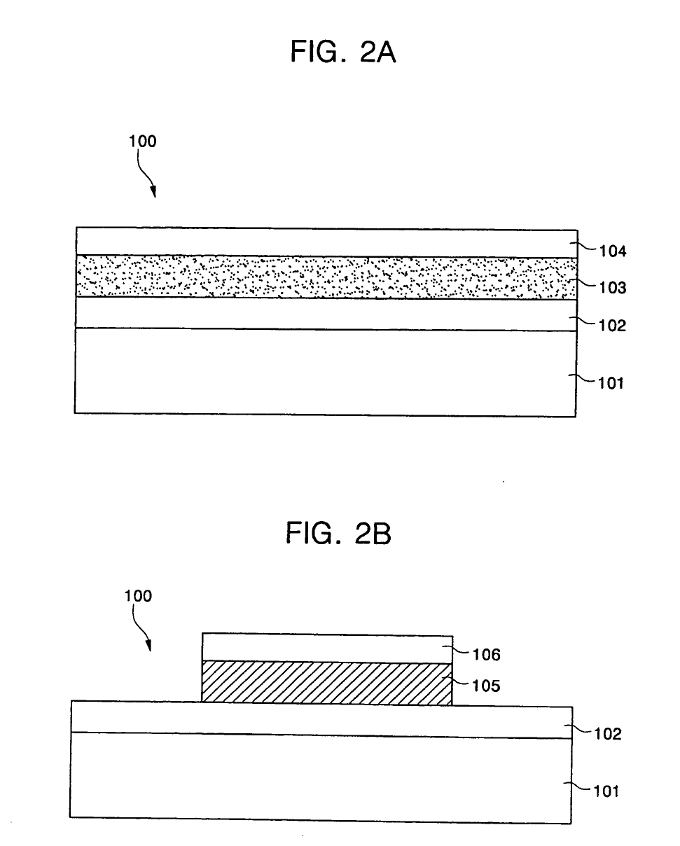

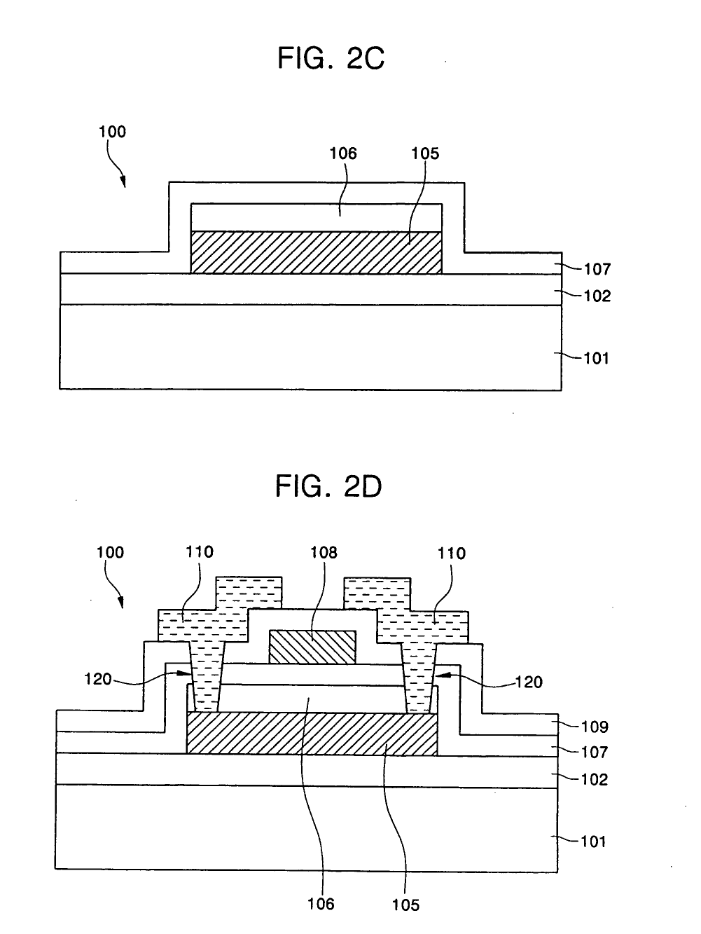

FIGS. 2A, 2B, 2C, and 2D are cross-sectional views illustrating a process of fabricating thin film transistor 100 according to the present invention. FIG. 2A is a cross-sectional view illustrating a process whereby a buffer layer 102, an amorphous silicon layer 103 and a first insulation film 104 are sequentially and continuously formed on an insulation substrate 101. The buffer layer 102 is formed as a single or double layer of continuous silicon oxide film or silicon nitride film on a transparent insulation substrate 101. The transparent substrate 101 may be formed of plastic, glass, or other suitable transparent material. The buffer layer facilitates crystallization of the semiconductor layer by preventing diffusion of moisture or impurities from a substrate under the buffer layer and/or by controlling the heat transfer rate during crystallization.

Subsequently, amorphous silicon layer 103 is continuously formed on the buffer layer, and the first insulation film 104 is continuously formed on the amorphous silicon layer 103. The amorphous silicon layer 103 and the first insulation film 104 may be continuously formed using a chemical vapor deposition method which can be used to form an oxide film, a nitride film or a silicon layer depending on the type of gas injected.

Illustratively, the amorphous silicon layer 103 and first insulation film 104 may be continuously formed as follows. The amorphous silicon layer 103 is formed using a mixture of silane gas (SiH₄) and hydrogen gas (H₂). The first insulation film 104 is formed either by injecting a mixture of silane gas, an oxygen (O₂) gas or by injecting a mixture of silane gas and nitrogen (N₂) gas. When oxygen gas is used, the first insulation layer comprises a silicon oxide film. When nitrogen gas is used, the first insulation layer 104 comprises a silicon nitride film.

Preferably, the first insulation film is formed of a silicon oxide film which produces superior interface characteristics between the amorphous silicon layer 103 and the gate insulation film 104. These superior interface characteristics include matched grain orientation, high electron mobility, and low leakage current because the first insulation film is also used as a gate insulation film.

Furthermore, the first insulation film 104 is preferably formed to about 50 Å to about 400 Å thick. If the first insulation film 104 is too thick, crystallization energy may not uniformly transfer to the amorphous silicon layer 103 under the first insulation film 104 during the crystallization process. If the first insulation film is too thin, the amorphous silicon layer under 103 the first insulation film 104 may not be protected from contamination.

If an interface between the amorphous silicon layer 103 and first insulation film 104 is unclear, or if the first insulation film 104 is formed in such a way that chemical composition (ratio of silicon to oxygen or ratio of silicon to nitrogen) of the first insulation film 104 is unstable due to the gas change, a thin film layer having superior interface characteristics between the amorphous silicon layer 103 and the first insulation film 104 may be created by forming the first insulation film 104 after purging for several seconds to several minutes using an inert gas such as argon (Ar) and helium (He) after forming an amorphous silicon layer.

FIG. 2B is a cross-sectional view illustrating a process of forming the amorphous silicon layer 103 and the first insulation film 104 into a polycrystalline silicon layer pattern 105 and a first insulation film pattern 106. The polycrystalline silicon layer pattern 105 and first insulation film pattern 106 may be formed by first patterning the amorphous silicon layer 103 and the first insulation layer 104, and then crystallizing the amorphous silicon layer 103 to form the polycrystalline silicon layer pattern 105. Alternatively, the amorphous silicon layer pattern and first insulation film pattern 106 may be formed by first crystallizing the amorphous silicon layer 103 into a polycrystalline silicon layer and then using a photoresist to pattern both the polycrystalline layer 105 and the first insulating layer 106.

Using the above techniques prevents non-intended formation of oxides because the surface of the amorphous silicon layer 103 is covered by the first insulation film 104. In contrast, non-intended oxides may easily form during crystallization on the exposed surface of the conventional amorphous silicon layer 12. Furthermore, while the conventional polycrystalline silicon layer pattern or amorphous silicon layer pattern may be damaged and impurities adsorbed there or formed thereon during the ashing or wet etching processes used to remove the photoresist pattern, the present invention prevents the foregoing problems by covering the surface of the amorphous silicon layer pattern 103 with the first insulation film 104 or the polycrystalline silicon layer pattern 105 with the first insulation pattern 106.

The crystallization process at the invention may be performed using one or more crystallization methods selected from a group that includes, but is not limited to, rapid thermal annealing, solid phase crystallization, excimer laser annealing, metal induced crystallization, metal induced lateral crystallization, and sequential lateral solidification. Preferably, the patterning process is performed by dry etching using CF₄ gas where the first insulation film is a silicon oxide film since an etching selectivity ratio of silicon oxide that is the first insulation film to amorphous silicon or polycrystalline silicon is almost zero in the presence of CF₄ gas, that two thin film layers can be etched simultaneously.

FIG. 2C is a cross-sectional view illustrating a process of forming a second insulation film 107 on the substrate 101. As illustrated in FIG. 2C, the second insulation film 107 is formed on a substrate 101 on which a buffer layer 102, a polycrystalline silicon layer pattern 105, and a first insulation film pattern 106 are sequentially formed. The second insulation film 107 may be a silicon oxide film, a silicon nitride film, or an organic insulation film. Preferably, the second insulation film 107 is formed in such a way that the total thickness of the second insulation film 107 and the first insulation film 106, (e.g., a thickness of the gate insulation film(s)) is about 800 Å to about 1500 Å. Namely, if a thickness of the first insulation film 106 is about 400 Å, the thickness of the second insulation film 107 is about 400 Å to about 1100 Å since the first insulation film 106 and the second insulation film together comprise the gate insulation film. The second insulation film 107 should be additionally formed as described above because a gate insulation film formed only of the first insulation film 106 cannot provide insulating properties sufficient to withstand the applied voltages.

FIG. 2D is a cross-sectional view of a completed thin film transistor 100 having a gate electrode 108 formed on the second insulation film 107, an interlayer insulation film 109 formed on the gate electrode 108 and the second insulation film 109, and source/drain electrodes 110 formed in an opening 120 patterned through the interlayer insulation film 109, the second insulation film 107, and the first insulation film 106. As illustrated in FIG. 2D, a gate electrode 108 is formed on the second insulation film 107. Preferably, the gate electrode 108 comprises a metal such as Al, AlNd, Cr, Mo or MoW, or a compound comprising one or more of the metals. Additionally, the gate electrode 108 may be used as a mask during an impurity ion implantation process to define the source/drain and channel regions, on the polycrystalline silicon layer pattern 105.

Subsequently, an interlayer insulation film 109 is formed as a single layer or double layer of silicon oxide film or silicon nitride film to cover the gate electrode 108, and contact holes 120 for exposing a part of the source/drain regions are formed by etching pre-determined regions of the interlayer insulation film 109, the first insulation film 106, and second insulation film 107.

Next, the source/drain electrodes 110 may be formed by depositing and patterning source/drain electrode forming materials on the front surface of the substrate.

Therefore, the present invention provides a thin film transistor having improved operating characteristics such as reduced leakage current and increased electron mobility. These advantages result in part from the superior interface characteristics between the thin film transistor's gate insulation film(s) 106 and 107 and polycrystalline silicon layer pattern 105 due to matched grain orientation, prevention of non-intended formation of oxides, and prevention of formation of contaminants by continuously depositing a first insulation film that is a part of gate insulation film over the amorphous silicon layer 105. Furthermore, the present invention provides a thin film transistor fabrication method capable of shortening the fabrication process by eliminating the conventional cleaning steps needed to remove non-intended oxides and contaminants.

While the invention has been described in terms of exemplary embodiments, those skilled in the art will recognize that the invention can be practiced with modifications in the spirit and scope of the appended claims. These examples given above are merely illustrative and are not meant to be an exhaustive list of all possible designs, embodiments, applications or modifications of the invention.

1. A thin film transistor, comprising:
a substrate;
a polycrystalline silicon layer pattern continuously covered by a first insulation film pattern and formed on the substrate;
a second insulation film formed on the first insulation film pattern;
a gate electrode formed on the second insulation film; and
an interlayer insulation film formed on the second insulation film and the gate electrode.

2. The thin film transistor of claim 1, wherein the first insulation film pattern and the second insulation film are gate insulation films.

3. The thin film transistor of claim 2, wherein the gate insulation films together have a total thickness of about 800 Å to about 1500Å.

4. The thin film transistor of claim 1, wherein the first insulation film pattern has thickness of about 50 Å to about 400Å.

5. The thin film transistor of claim 1, wherein the first insulation film pattern has thickness of about 200Å.

6. The thin film transistor of claim 1, wherein the first insulation film pattern is an oxide film.

7. The thin film transistor of claim 1, wherein the first insulation film pattern or second insulation film are each one of a silicon oxide film or a silicon nitride film.

8. The thin film transistor of claim 1, wherein the second insulation film is an organic insulation film.

9. The thin film transistor of claim 1, wherein the polycrystalline silicon layer pattern and first insulation film pattern are by first crystallizing and then patterning an amorphous silicon layer covered by a continuously formed first insulation film.

10. The thin film transistor of claim 1, wherein the polycrystalline silicon layer pattern and first insulation film pattern are by first patterning and then crystallizing an amorphous silicon layer covered by a continuously formed first insulation film.

11. The thin film transistor of claim 1, wherein the polycrystalline silicon layer pattern and first insulation film pattern are patterned by CF₄ gas.

12. The thin film transistor of claim 1, wherein the gate electrode is formed of Al, AlNd, Cr, Mo, MoW or a compound thereof.

13. The thin film transistor of claim 1, wherein the interlayer insulation film is formed of a single or double layer of silicon oxide film or of a single or double layer of silicon nitride film.

14. A method for fabricating a thin film transistor film, comprising:
forming an amorphous silicon layer on an substrate;
continuously forming a first insulation film on the amorphous silicon layer;
forming a polycrystalline silicon layer pattern and a first insulation film pattern out of the amorphous silicon layer and first insulation film;
forming a second insulation film on the substrate;
forming a gate electrode on the second insulation film; and
forming an interlayer insulation film on the gate electrode and the second insulation film.

15. The method of claim 14, wherein the step of forming a polycrystalline silicon layer pattern and a first insulation film pattern out of the amorphous silicon layer and first insulation film includes first crystallizing the amorphous silicon layer into a polycrystalline silicon layer, and then patterning the polycrystalline silicon layer and the first insulation film to form the polycrystalline silicon layer pattern and the first insulation film pattern, respectively.

16. The method of claim 15, wherein the patterning process includes performing etching using CF₄ gas.

17. The method of claim 15, wherein the crystallizing process comprises performing crystallization using one or more of methods selected from the group consisting of rapid thermal annealing, solid phase crystallization, excimer laser annealing, metal induced crystallization, metal induced lateral crystallization, and sequential lateral solidification.

18. The method of claim 14, wherein the step forming a polycrystalline silicon layer pattern and a first insulation film pattern out of the amorphous silicon layer and first insulation film includes first patterning the amorphous silicon layer and first insulation film, and then crystallizing the patterned amorphous silicon layer into polycrystalline silicon layer pattern and the patterned first insulation film.

19. The method of claim 18, wherein the patterning process is a process of performing etching using CF₄ gas.

20. The method of claim 18, wherein the crystallizing process comprises performing crystallization using one or more of methods selected from the group consisting of rapid thermal annealing, solid phase crystallization, excimer laser annealing, metal induced crystallization, metal induced lateral crystallization, and sequential lateral solidification.
